(19) United States
(12) Patent Application Publication
(10) Pub. No.: US 2005/0156277 A1
(43) Pub. Date: Jul. 21, 2005

(54) Semiconductor device

(75) Inventors: Hideo Nakano, Takatsuki-shi (JP); Shoji Yoshida, Yokohama-shi (JP); Masakatsu Maeda, Mukou-shi (JP)

Correspondence Address: STEVENS DAVIS MILLER & MOSHER, LLP, 1615 L STREET, NW, SUITE 850, WASHINGTON, DC, 20036, US

(73) Assignee: MATSUSHITA ELECTRIC INDUSTRIAL CO., LTD., Osaka (JP)

(21) Appl. No.: 11/011,788

(22) Filed: Dec. 15, 2004

(30) Foreign Application Priority Data
Dec. 19, 2003 (JP) 2003-422987

(51) Int. Cl. H01L 29/00

(52) U.S. Cl. 257/532

(57) ABSTRACT

There is provided a semiconductor device, wherein a digital circuit region and an analog circuit region are located independently. A power supply wiring and a ground wiring are placed on the periphery of each circuit region and are connected to elements in each circuit region. A MOS capacitor is formed under the power supply wiring and the ground wiring. The terminals of the MOS capacity are connected to the power supply wiring and the ground wiring. Pads are placed in each circuit region surrounded by the power supply wiring, the ground wiring, and the MOS capacitor and are connected to the elements of each circuit region.

### BACKGROUND OF THE INVENTION

1. Field of the Invention

The present invention relates to a semiconductor device. More particularly, the present invention relates to a semiconductor device which takes measures against interference and noise between circuit blocks in a semiconductor integrated circuit in which an analog circuit block and a digital circuit block are combined on a single chip.

2. Background Art

With the recent popularity of semiconductor integrated circuit devices having larger packing densities and higher performance, an integrated circuit used for cellular phones and so on has been intended to have a structure that a plurality of analog and digital circuits, such as a transmitting circuit, a receiving circuit, and a PLL circuit, are combined on one and the same substrate through the use of BiCMOS process technology.

Such an integrated circuit generally receives a signal of 10 to 30 MH_{Z} from an external temperature-compensated crystal oscillator (TCXO) or the like as a reference signal for controlling circuit operation. Then, the frequency of the reference signal is changed into a required frequency by dividing and multiplication at its internal circuit, so that the resulting frequency is used as, for example, a phase-comparison signal for the PLL circuit and a reference signal for the digital circuit.

Thus, in the inside of the integrated circuit, signals having the frequencies of the divided or multiplied waves are generated besides the reference signal. Particularly, in the digital circuits, those signals take the form of rectangular waves, including odd-order higher harmonic waves. In addition, their amplitudes represent power supply-to-ground voltages and are of relatively large voltage amplitudes in terms of the signal amplitude level of the analog circuits.

Furthermore, the transmitting circuit block and the receiving circuit block of the analog circuit section have a circuit which inputs and outputs a high-frequency signal and a local oscillation signal of 1 to 2 GH_{Z}, a circuit which divides or multiplies the frequencies of those signals, and a circuit which changes the resulting frequencies using a mixer or the like. Those circuits generate divided waves and higher harmonic waves of the high-frequency signal and the local oscillation signal, and also generate circuit noise.

FIG. 6 is a schematic block diagram of a relate art semiconductor integrated circuit (semiconductor device). In this semiconductor integrated circuit, a digital circuit region 3 and an analog circuit region 2 are formed on one and the same IC substrate (semiconductor substrate) 1 together as shown in FIG. 6. In the digital circuit region 3, a digital circuit power supply pad 20 and a digital circuit ground pad 21 are each connected to a package electrode 30 via a bonding wire 34, and then the package electrodes 30 are connected to a digital circuit IC external power supply 32a and an IC external ground 33, the digital circuit IC external power supply 32a and the IC external ground 33 being external to the IC. In the analog circuit region 2, an analog circuit power supply pad 25 and an analog circuit ground pad 26 are each connected to a package electrode 30 via a bonding wire 34, and then the package electrodes 30 are connected to an analog circuit IC external power supply 32b and an IC external ground 33, the analog circuit IC external power supply 32b and the IC external ground 33 being external to the IC.

As a bypass capacitor, a digital circuit IC external capacitor 31a and an analog circuit IC external capacitor 32b are connected between the power supply and the ground which are external to the IC.

In FIG. 6, a broken line represents a package. The inside of the broken line represents the IC substrate side 35. The outside of the broken line represents the outside of the IC substrate 36.

In a semiconductor device having such a structure, the signal and its higher harmonic waves, etc. of the digital circuit have propagated to or interfered with other circuit blocks' signal wirings, power supply wirings, or ground wirings through its substrate, signal wiring, power supply wiring or ground wiring. In consequence, the related art semiconductor device have had a problem that unwanted noise and spurious have occurred in the circuit output signals of other circuit blocks to induce deterioration in the S/N (Signal/Noise) and the C/N (Carrier/Noise) of their signals and desensitization to input signals of the circuits.

In the following, the related art will be described with reference to FIGS. 6, 7 and 8. In the related art semiconductor device, in order to prevent the propagation of the signals, noises, etc. between the circuit blocks, a digital circuit region 3 and analog circuit regions 2 have been spaced from one another, and a substrate contact 6 has been placed between the circuit regions 2 and 3 as shown in, for example, FIG. 7.

Also, as shown in FIG. 8, another example of the related art has employed a structure that an analog circuit region 2 has been separated from a digital circuit region 3 by a trench 10, and a digital circuit element 39, such as an n-channel MOS transistor, has been separated by an n well 7b (see, for example, Japanese Patent Laid-Open No. 12717/1998).

In FIG. 8, reference numerals 7a, 7b, and 7c represent an n⁺ diffusion layer, an n well, and an n⁺ buried layer, respectively. Reference numerals 8a, 8b, and 8c represent a p well, a p-type substrate, and a p⁺ diffusion layer, respectively. Reference numerals 9, 11, and 38 represent a LOCOS region, an n-type epitaxial layer, and an NPN transistor, respectively.

As to semiconductor integrated circuit devices used for the radio transmission section of cellular phones, the combination of analog and digital circuits is becoming popular as they become smaller, have higher degrees of integration, and drop in cost.

IN such semiconductor integrated circuits, when the actuating signal, its higher harmonic waves, etc. of the digital circuit have propagated to or interfered with the signal wiring, power supply wiring, or ground wiring of the analog circuit block through their substrate, its signal wiring, power supply wiring, or ground wiring, the following problem has arisen; even in case where a signal of the digital circuit has a low frequency, for example, on the order of 10 MHz, its frequency may be changed to a radio-frequency band on the order of 1 GHz by an analog circuit such as a mixer. As a result, spurious and noise having frequency bands used for transmission and reception occur to induce deterioration in characteristics, such as deterioration in the S/N and the C/N of the signals and desensitization to the input signals of the circuits.

IN order to prevent such interference between the circuit blocks, it is necessary not to transmit actuating signals within a circuit to other circuits and receive unnecessary signals from other circuits.

As a result, it is considered that substrate contacts are placed between the circuit blocks and measures to cut off their via-substrate interference path by the use of well isolation and trench isolation are taken. However, these measures bring about an increase in chip size to increase the integrated circuit production cost.

Also, in case where the interference between the circuit blocks is suppressed by some technique, such as the use of the substrate contact, well isolation, or trench isolation, its effect is further increased by fixing the potential of the back of the substrate with ground potential, or power supply potential. However, in a package employing a lead frame, such as a common QFP package, it becomes necessary to expose, from the package, a part of the lead frame which is connected to the substrate to provide the back of the substrate with a ground potential and to provide a terminal for grounding. In addition, like flip-chip mounting, in a package having a mounting configuration that the back of the substrate of a semiconductor device is not opposed to the substrate surface on which the semiconductor device is mounted, the application of a ground potential to the back of the substrate is difficult in itself.

Furthermore, as to the power supply section and the ground section of the circuits, since their wirings are required to be connected to terminals, such as wire bonding pads, which are connected to the outside of the semiconductor substrate, the power supply wiring and the ground wiring have a common impedance depending on the arrangement of the circuit blocks. As a result, signals and noise have circulated in the power supply wiring and the ground wiring, which has posed a problem that its circuit characteristics have deteriorated. Thus, it has heretofore been necessary to take a measure that a bypass capacitor is added between the power supply and the ground outside of the semiconductor device.

### SUMMARY OF THE INVENTION

The present invention provides a semiconductor device in which an analog circuit block and a digital circuit block are combined and which is capable of preventing deterioration in characteristics attributed to the propagation and interference of signals and noises between the circuit blocks.

In order to prevent the deterioration in circuit characteristics, the invention provides a semiconductor device in which an analog circuit block and a digital circuit block are combined on a single chip, the semiconductor device comprising a semiconductor substrate, first and second circuit regions which are independently provided on the semiconductor substrate, a digital circuit block which comprises first elements and is formed in the first circuit region, and analog circuit block which comprises a second element and is formed in the second circuit region, a first power supply wiring and a first ground wiring which are placed so as to surround the first circuit region and are connected to the first elements, a second power supply wiring and a second ground wiring which are placed so as to surround the second circuit region and are connected to the second element, a first capacitor which is placed so as to surround the first circuit region and is connected between the first power supply wiring and the first ground wiring, and a second capacitor which is placed so as to surround the second circuit region and is connected between the second power supply wiring and the second ground wiring.

As the first and second capacitors, there are, for example, first and second MIS capacitors having a MIS structure respectively.

The first MIS capacitor comprises a first semiconductor region, a first dielectric film, and a first polysilicon electrode and is formed so as to overlap with the first power supply wiring and the first ground wiring, the first semiconductor region being formed in a first element region under the first power supply wiring and the first ground wiring so as to have a different conductivity type from that of a second element region under the first circuit region, the first dielectric film and the first polysilicon electrode being stacked on the first semiconductor region in that order. Also, the second MIS capacitor comprises a second semiconductor region, a second dielectric film, and a second polysilicon electrode and is formed so as to overlap with the second power supply wiring and the second ground wiring, the second semiconductor region being formed in a third element region under the second power supply wiring and the second ground wiring so as to have a different conductivity type from that of a fourth element region under the second circuit region, the second dielectric film and the second polysilicon electrode being stacked on the second semiconductor region in that order.

Then, the first semiconductor region is connected to the first power supply wiring via a plurality of first power supply contacts, and the first polysilicon electrode is connected to the first ground wiring via a plurality of first ground contacts. Also, the second semiconductor region is connected to the second power supply wiring via a plurality of second power supply contacts, and the second polysilicon electrode is connected to the second ground wiring via a plurality of second ground contacts.

In the above configuration, the first power supply wiring and the first ground wiring have a gap at a place on the periphery of the first circuit region, and the second power supply wiring and the second ground wiring have a gap at a place on the periphery of the second circuit region.

The first power supply wiring and the first ground wiring may surround the periphery of the first circuit region continuously, and the second power supply wiring and the second ground wiring may surround the periphery of the second circuit region continuously.

As the first and second capacitors, it is also possible to use, for example, first and second MIM capacitors having a MIM structure respectively.

The first MIM capacitor comprises the first power supply wiring, the first ground wiring, and the first dielectric film, the first power supply wiring comprising a different wiring layer from that of the first ground wiring and being formed so as to overlap with the first ground wiring with the first dielectric film interposed. Also, the second MIM capacitor comprises the second power supply wiring, the second ground wiring, and the second dielectric film, the second power supply wiring comprising a different wiring layer from that of the second ground wiring and being formed so as to overlap with the second ground wiring with the second dielectric film interposed.

Then, the first ground wiring is connected to the semiconductor substrate via a first substrate contact, and the second ground wiring is connected to the semiconductor substrate via a second substrate contact.

In the above configuration, the first power supply wiring and the first ground wiring have a gap at a place on the periphery of the first circuit region, and the second power supply wiring and the second ground wiring have a gap at a place on the periphery of the second circuit region.

The first power supply wiring, the first ground wiring, and the first dielectric film may surround the periphery of the first circuit region continuously, and the second power supply wiring, the second ground wiring, and the second dielectric film may surround the periphery of the second circuit region continuously.

Also, according to the invention, it is preferable that first and second pads used for external connections and each connected to the first and second elements, that is, pads which are connected to the outside of the semiconductor device, such as power supply terminals, ground terminals, input terminals and output terminals, by bonding wires or the like be placed in the first and second circuit regions respectively.

Further, it is preferable that a plurality of first wirings be placed parallel to one another above the first circuit region in such a manner that every other one of the first wirings is connected to the first power supply wiring, and the remaining first wirings are connected to the first ground wiring. Likewise, it is preferable that a plurality of second wirings be placed parallel to one another above the second circuit region in such a manner that every other one of the second wirings is connected to the second power supply wiring, and the remaining second wirings are connected to the second ground wiring.

According to the semiconductor device of the invention, the periphery of each circuit region is surrounded by the power supply wiring and the ground wiring. Further, the periphery of each circuit region is surrounded by the capacitor, that is, the MIS capacitor or the MIM capacitor, in such a manner that the capacitor lies between the power supply wiring and the ground wiring. Still further, another capacitor is connected between the power supply wiring and the ground wiring which are adjacent to each circuit region. Thus, a bypass capacitor can be formed at a location where is not subject to the influence of the common impedance of the power supply wiring and the ground wiring. As a result, unwanted signals and noises which circulate in the power supply wiring and the ground wiring can be released from the power supply terminal and the ground terminal to the outside of each circuit by circuit region, by which the propagation and interference of signals and noises to the other circuits can be suppressed to prevent the deterioration in characteristics of the semiconductor device in which an analog circuit block and a digital circuit block are combined on a single chip.

In addition, in case where a MIS capacitor is formed as the capacitor, the semiconductor region under each circuit region (e.g. p-type semiconductor region) can be laterally isolated by the semiconductor region under the power supply wiring and the ground wiring (e.g. n-type semiconductor region), by which the propagation and interference of signals and noises between the circuit regions can be suppressed further.

In case where a MIM capacitor is formed as the capacitor, the actuating signals and their higher harmonic wave components of the first circuit region in which the digital circuit block is formed are released from the substrate contact to the digital circuit ground wiring or the analog circuit ground wiring before they are transmitted to the second circuit region, in which the analog circuit block is formed, via the element region under the power supply wiring and the ground wiring, by which the interference of signals between the first and second circuit regions can be suppressed further.

Furthermore, since the MIS capacitor or the MIM capacitor is formed so as to overlap with the power supply wiring and the ground wiring of each circuit region, an increase in chip size is not involved in view of the related art.

### BRIEF DESCRIPTION OF THE DRAWINGS

FIG. 1 is a schematic plan view showing a structure used in an embodiment 1 of the present invention.

FIG. 2 is a schematic sectional view showing a structure used in an embodiment 1 of the present invention.

FIG. 3 is a schematic plan view showing a structure used in an embodiment 2 of the present invention.

FIG. 4 is a schematic perspective view in section showing a structure used in an embodiment 2 of the present invention.

FIG. 5 is a schematic plan view showing a structure used in embodiments 1 and 2 of the present invention.

FIG. 6 is a plan view showing a structure used for a related art semiconductor device.

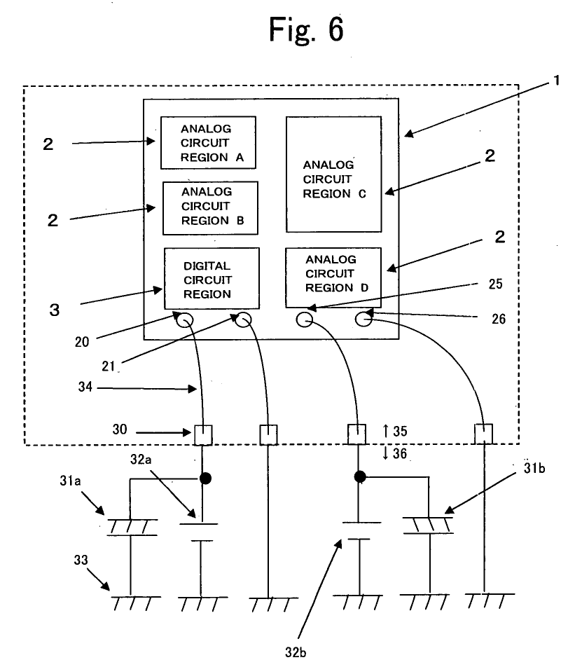

FIG. 7 is a plan view showing a structure used for another related art semiconductor device.

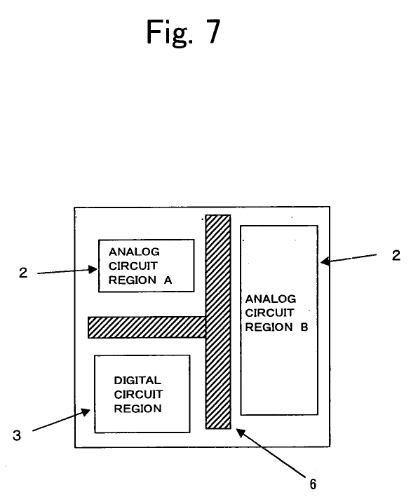

FIG. 8 is a sectional view showing a structure used for still another related art semiconductor device.

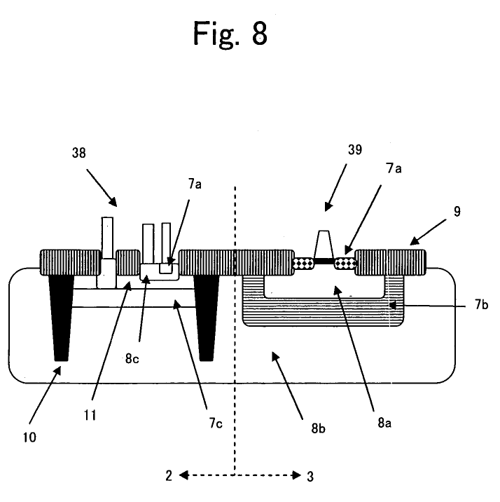

### DESCRIPTION OF THE PREFERRED EMBODIMENTS

In the following, embodiments according to the invention will be described with reference to the drawings.

(Embodiment 1)

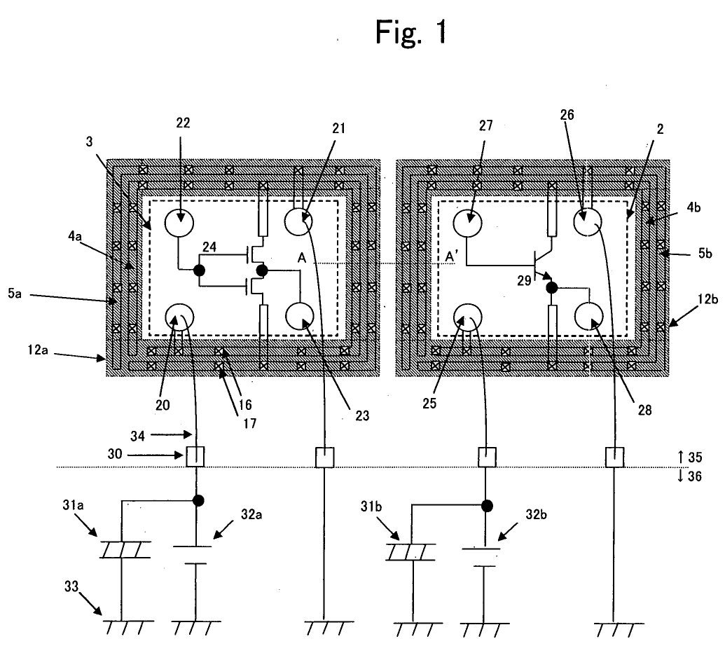

In Embodiment 1, a semiconductor device in which a digital circuit block and an analog circuit block are combined on one and the same semiconductor substrate is explained with reference to FIG. 1. The outside shape of its IC substrate is not shown in FIG. 1.

With this semiconductor device, a digital circuit region 3 and an analog circuit region 2 are adjacent to each other and are independently placed as shown in FIG. 1. In the digital circuit region 3, a digital circuit block is constituted by placing MOS transistors 24 and so on. In the analog circuit region 2, an analog circuit block is constituted by placing a bipolar transistor 29 and so on.

Around the digital circuit region 3, a digital circuit power supply wiring 4a and a digital circuit ground wiring 5a, which are connected to the elements in the digital circuit region 3, are placed. The digital circuit power supply wiring 4a and the digital circuit ground wiring 5a have a gap at a place on the periphery of the digital circuit region 3 respectively. Furthermore, under the digital circuit power supply wiring 4a and the digital circuit ground wiring 5a, a MOS capacitor 12a, which is a kind of MIS capacitor, is formed, and the two electrodes of the MOS capacitor 12a are connected to the digital circuit power supply wiring 4a and the digital circuit ground wiring 5a respectively.

Around the analog circuit region 2, an analog circuit power supply wiring 4b and an analog circuit ground wiring 5b, which are connected to the elements in the analog circuit region 2, are placed. The analog circuit power supply wiring 4b and the analog circuit ground wiring 5b have a gap at a place on the periphery of the analog circuit region 2 respectively. Furthermore, under the analog circuit power supply wiring 4b and the analog circuit ground wiring 5b, a MOS capacitor 12b is formed, and the two electrodes of the MOS capacitor 12b are connected to the analog circuit power supply wiring 4b and the analog circuit ground wiring 5b respectively.

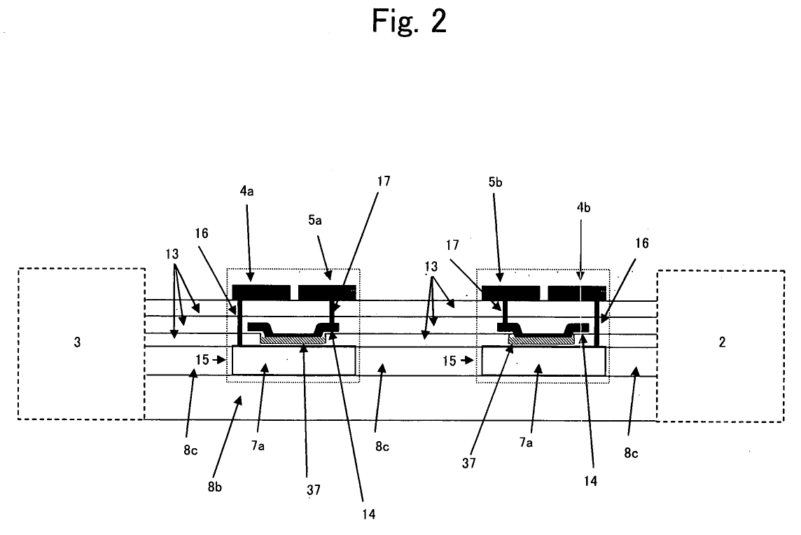

FIG. 2 represents a cross section taken along line A-A′ in FIG. 1. The MOS capacitor 12a comprises an n⁺ diffusion region (N-type semiconductor region) 7a, a MOS capacitor dielectric film 37, and a polysilicon electrode 14 which are formed in an element region 15 under the power supply wiring 4a and the ground wiring 5a. The MOS capacitor 12b comprises an n⁺ diffusion region (N-type semiconductor region) 7a, a MOS capacitor dielectric film 37, and a polysilicon electrode 14 which are formed in an element region 15 under the power supply wiring 4b and the ground wiring 5b. The n⁺ diffusion regions (N-type semiconductor regions) 7a are each connected by a plurality of power supply contacts 16 to the digital circuit power supply wiring 4a and the analog circuit power supply wiring 4b which are placed around the circuit region. Also, the polysilicon electrodes 14 are each connected by a plurality of ground contacts 17 to the digital circuit ground wiring 5a and the analog circuit ground wiring 5b which are placed around the circuit region. In FIG. 2, reference numerals 8b, 8c, and 13 represent a p-type substrate, p⁺ diffusion region, and an oxide film respectively.

As shown in FIG. 1, there are also provided a digital circuit power supply pad 20, an analog circuit power supply pad 25, a digital circuit ground pad 21, an analog circuit ground pad 26, a digital circuit input signal pad 22, an analog circuit input signal pad 27, a digital circuit output signal pad 23, and an analog circuit output signal pad 28 which are connected to the respective elements in the digital circuit and analog circuit regions 3 and 2. The various pads, which are connected to the outside of the semiconductor device by externally connecting parts, such as bonding wires 34 and package electrodes (IC terminals) 30, are placed in the circuit regions surrounded with the power supply wirings 4a and 4b, the ground wirings 5a and 5b, and the MOS capacitors 12a and 12b of the respective circuits.

Further, the power supply pad 20 is connected to the package electrode 30 via the bonding wire 34, and then the package electrode 30 is connected to a digital circuit IC external power supply 32a and a digital circuit IC external capacitor 32a. The power supply pad 25 is also connected to the package electrode 30 via the bonding wire 34, and then the package electrode 30 is connected to an analog circuit IC external power supply 32b and an analog circuit IC external capacitor 31b.

In addition, the ground pads 21 and 26 are each connected to the package electrode 30 via the bonding wire 34, and then the package electrodes 30 are each connected to an IC external ground 33.

As to the semiconductor device shown in FIG. 1, in the spot where the digital circuit region 3 and the analog circuit region 2 are adjacent to each other, as shown in FIG. 2, the p⁺ diffusion region 8c of the element region 15 under the respective circuit regions 3 and 2 is separated doubly by the n⁺ diffusion regions 7a under the power supply wirings 4a and 4b and the ground wirings 5a and 5b, that is, the n⁺ diffusion layer 7a of the MOS capacitor 12a placed around the digital circuit region 3 and the n⁺ diffusion region (N-type diffusion region) 7a of the MOS capacitor 12b placed around the analog circuit region 2. As a result, such a structure brings about the effect of preventing the actuating signals and their higher harmonic wave components of the digital circuit region 3 from interfering with the analog circuit region 2.

Furthermore, the MOS capacitors 12, which are placed under the power supply wirings and the ground wirings around the digital circuit region 3 and the analog circuit region 2, are each connected between the power supply and the ground as a bypass capacitor. Thus, in case where the signals, noises, etc. of the digital circuit region 3 circulate in the digital circuit power supply wiring 4a and the analog circuit power supply wiring 4b as well, it is possible to release them to the digital circuit ground pad 21 and the analog circuit ground pad 26 via the MOS capacitors 12a and 12b.

Also, by providing an external capacitor between the IC external power supply and the external ground, the circulation of signals and noises has been heretofore suppressed. However, on the prevention of the circulation in the power supply on the semiconductor substrate, sufficient effect has not been obtained often due to the common impedance of the package electrodes 30 and the bonding wires 34.

Contrarily, in the configuration shown in FIG. 1, capacitors can be connected to locations where the circuit elements present nearby and the influence of the wiring impedances of the power supply wirings 4a and 4b and the ground wirings 5a and 5b is little. As a result, at the digital circuit region 3 and the analog circuit region 2, the circulation and interference of unwanted signals to their power supplies can be suppressed. At this time, the power supply contacts 16, which are connected between the power supply wiring 4a and the MIS capacitor 12a and which are connected between the power supply wiring 4b and the MIS capacitor 12b, are located as many as possible, and the same goes for ground contacts 17 which are connected between the ground wiring 5a and the MIS capacitor 12a and which are connected between the ground wiring 5b and the MIS capacitor 12b. Through those connections, wiring impedance can be reduced further. Incidentally, in this configuration, the size of the semiconductor substrate is the same as that of the relate art because the MIS capacitors 12a and 12b are located under the power supply wirings 4a and 4b and the ground wirings 5a and 5b.

Furthermore, signals and noises from the digital circuit region 3 have often circulated in the pads to which the other circuit elements are connected via the substrate. However, the above problem is solved by using the following configuration. As shown in FIG. 1, by placing the power supply pads 20 and 25, the ground pads 21 and 26, the input pads 22 and 27, and the output pads 23 and 28, which are each connected to the elements of the digital circuit region 3 and the analog circuit region 2, in their circuit regions 3 and 2 respectively, the isolation of the element region under the MOS capacitor 12a and element region under the MOS capacitor 12b is performed between the respective pads 20 to 23 and 25 to 28 and the other circuit regions 2 and 3. In addition, since the power supply wiring, the ground wiring, and the bypass capacitor are placed around the respective circuit regions 2 and 3, it is possible to prevent the circulation of signals and noises from the pads 20 to 23 and 25 to 28 to the other circuit regions 2 and 3 through the substrate, and the circulation of signals and noises from the other circuit regions 2 and 3 to the pads 20 to 23 and 25 to 28.

By utilizing the above configuration, in the semiconductor integrated circuit wherein the analog circuit block and the digital circuit block are combined on a single chip, the propagation or interference of signals and noises to other circuit blocks can be suppressed to prevent the deterioration in its circuit characteristics.

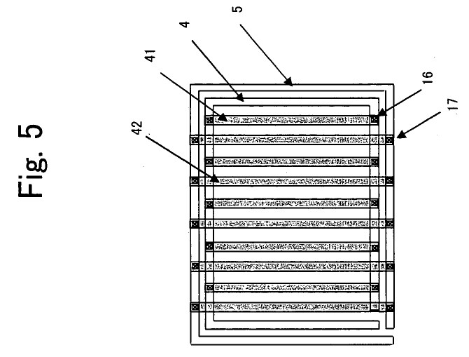

Further, in addition to the configuration shown in FIG. 1, power supply wirings 41 and ground wirings 42 may be formed above the digital circuit region 3 or the analog circuit region 2 as shown in FIG. 5. The power supply wirings 41 and the ground wirings 42 are formed using the same wiring layer e.g. a third layer aluminum wiring in such a manner that they are alternately placed in parallel with each other. The power supply wirings 41 are connected to the power supply wiring 4 which comprises, for example, a second layer aluminum wiring via the power supply contact 16, and the ground wirings 42 are connected to the ground wiring 5 which comprises, for example, a second layer aluminum wiring via the ground contact 17. The power supply wiring 4 is representative of the power supply wirings 4a and 4b, and the ground wiring 5 is representative of the ground wirings 5a and 5b. As a result, a capacitor can be formed between the power supply wiring 41 and the ground wiring 42.

The value of the capacitors can be increased as the spacings between the parallel wirings become narrow, so that the capacitors perform the same function as that of the MOS capacitors. Also, since the power supply wirings 41 and the ground wirings 42 are placed above each circuit region, the capacitors also have a shielding effect of preventing the propagation of signals and noises to the wirings which cross over their own circuit and then are connected to another circuit region.

Although Embodiment 1 has been described by taking as an example the power supply wiring and the ground wiring which have a gap at a place on the periphery of each circuit region, the power supply wiring and the ground wiring may continuously surround the periphery of each circuit region.

In addition, explanations for effects brought about by giving the gap to the power supply wirings and the ground wirings are as follows. In case where the gap is given, there is an advantage that it is easy to draw the wirings from each circuit block (the securing of wiring regions). In case where the gap is not given, a current flows through the ringed conductors due to a change in magnetic flux around the wirings to bring about the possibility of the occurrence of noise, but the occurrence can be avoided by giving the gap to them.

In the above configuration of Embodiment 1, MIM capacitors can be formed instead of MOS capacitors.

(Embodiment 2)

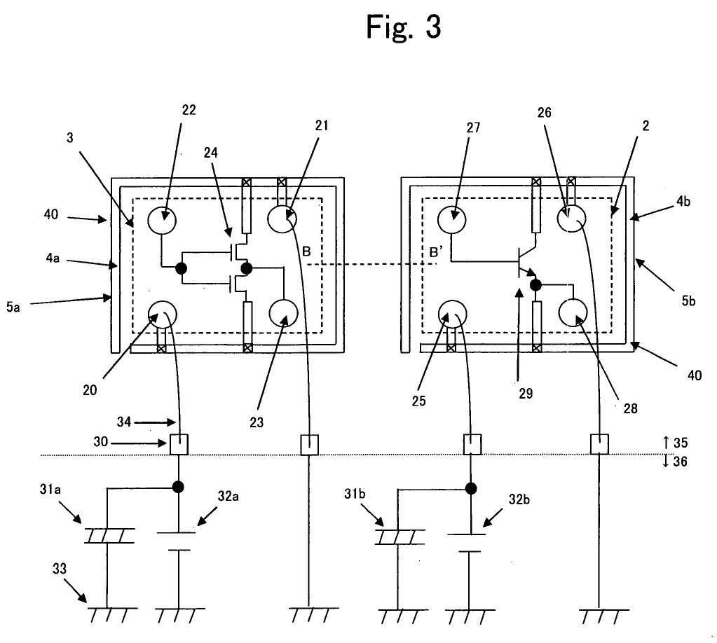

Next, Embodiment 2 will be explained with reference to FIG. 3. In a semiconductor device shown in FIG. 3, a digital circuit region 3 and an analog circuit region 2 are adjacent to each other and are independently placed. In the digital circuit region 3, a digital circuit is constituted by placing MOS transistors 24 and so on. In the analog circuit region 2, an analog circuit is constituted by placing a bipolar transistor 29 and so on.

Around the circuit regions 3 and 2, a digital circuit power source wiring 4a, a digital circuit ground wiring 5a, an analog circuit power source wiring 4b, and an analog circuit ground wiring 5b, which are connected to the elements in the circuit regions 3 and 2 respectively, are placed in such a manner that they have a gap at a place on the periphery of the circuit regions 3 and 2.

In FIG. 3, the outside shape of the IC substrate is not shown. Also, in this embodiment, the digital circuit power supply wiring 4a and the digital circuit ground wiring 5a are made up of different wiring layers and are placed in a state that they are vertically opposed to each other. Likewise, the analog circuit power supply wiring 4b and the analog circuit ground wiring 5b are made up of different wiring layers and are placed in a state that they are vertically opposed to each other.

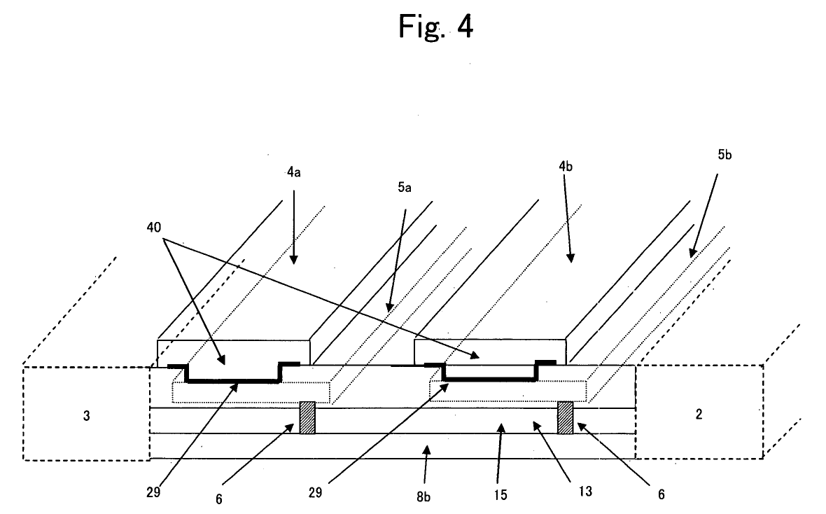

FIG. 4 shows a cross section taken along line B-B′ in FIG. 3. In this embodiment, the digital circuit power supply wiring 4a and the analog circuit power supply wiring 4b comprise a different wiring layer from that of the digital circuit ground wiring 5a and the analog circuit ground wiring 5b. In addition, a MIM capacitor dielectric film 29 is formed between not only the layers of the digital circuit power supply wiring 4a and the digital circuit ground wiring 5a but the layers of the analog circuit power supply wiring 4b and the analog circuit ground wiring 5b, which brings about the formation of MIM capacitors 40.

Like Embodiment 1 shown in FIG. 1, by adopting the above configuration, a bypass capacitor is formed between not only the power supply wiring 4a and the ground wiring 5a but the power supply wiring 4b and the ground wiring 5b.

With the semiconductor device shown in FIG. 3, at a spot where the digital circuit region 3 and the analog circuit region 2 are adjacent to each other, the digital circuit ground wiring 5a and the analog circuit ground wiring 5b are connected to a p-type substrate 8b via a substrate contact as shown in FIG. 4. Thus, before the actuating signal and its higher harmonic wave components of the digital circuit region 3 are transmitted to the analog circuit region 2 via an element region 15 under the power supply wirings 4a and 4b and the ground wirings 5a and 5b, they are released from the substrate contact 6 to the digital circuit ground wiring 5a or the analog circuit ground wiring 5b. As a result, the interference of the signal between the digital circuit region 3 and the analog circuit region 2 can be prevented.

Further, in this configuration, since the power supply wirings 4a and 4b and the ground wirings 5a and 5b become the electrode of the MIM capacitor 40 as they are, contact resistance does not occur in the state that the power supply wirings 4a and 4b and the ground wirings 5a and 5b are connected to the capacitor element (MIM capacitor 40) as opposed to Embodiment 1 shown in FIG. 1. Consequently, the effect of the bypass capacitors can be increased. Thus, when the signals, noises, etc. of the digital circuit region 3 circulate in the digital circuit power supply wiring 4a and the analog circuit power supply wiring 4b as well, it is possible to release them to the digital circuit ground pad 21 or the analog circuit ground pad 26 via the MIM-type capacitor 40.

Also, by providing an external capacitor between an IC external power supply and an external ground, the circulation of signals and noises has been heretofore suppressed. However, on the prevention of the circulation in the power supply on the semiconductor substrate, sufficient effect has not been obtained often due to the common impedance of the package electrodes 30 and the bonding wires 34.

Contrarily, in the configuration shown in FIG. 3, capacitors can be connected to locations where the circuit elements present nearby and the influence of the wiring impedances of the power supply wirings 4a and 4b and the ground wirings 5a and 5b is little. As a result, it is possible to suppress the circulation and interference of unwanted signals to the power supplies at the digital circuit region 3 and the analog circuit region 2.

Further, in addition to the configuration shown in FIG. 3, power supply wirings 41 and ground wirings 42 may be formed above the digital circuit region 3 or the analog circuit region 2 as shown in FIG. 5. The power supply wirings 41 and the ground wirings 42 are formed using the same wiring layer e.g. a third layer aluminum wiring in such a manner that they are alternately placed in parallel with each other. Then, the power supply wirings 41 are connected to the power supply wiring 4, which comprises, for example, a second layer aluminum wiring, via power supply contacts 16, and the ground wirings 42 are connected to the ground wiring 5, which comprises, for example, a second layer aluminum wiring, via ground contacts 17. The power supply wiring 4 is representative of the power supply wirings 4a and 4b, and the ground wiring 5 is representative of the ground wirings 5a and 5b. As a result, a capacitor can be formed between the power supply wiring 41 and the ground wiring 42 which are adjacent to each other.

The value of the capacitors can be increased as the spacings between the parallel wirings become narrow, so that the capacitors perform the same function as that of the MIM capacitors. Also, since the power supply wirings 41 and the ground wirings 42 are placed above each circuit region, the capacitors also have a shielding effect of preventing the propagation of signals and noises to the wirings which cross over their own circuit and then are connected to another circuit region.

Although Embodiment 2 has been described by taking as an example the power supply wiring and the ground wiring which have a gap at a place on the periphery of each circuit region, the power supply wiring, the ground wiring, and the dielectric film therebetween may continuously surround the periphery of each circuit region.

In addition, explanations for effects brought about by giving the gap to the power supply wirings and the ground wirings are as follows. In case where the gap is given, there is an advantage that it is easy to draw the wirings from each circuit block (the securing of wiring regions). In case where the gap is not given, a current flows through the ringed conductors due to a change in magnetic flux around the wirings to bring about the possibility of the occurrence of noise, but the occurrence can be avoided by giving the gap to them.

In the configuration in 2, MOS capacitors may be formed instead of MIM capacitors.

### INDUSTRIAL APPLICABILITY

As described above, the semiconductor integrated circuit device of the invention comprises an analog circuit and a digital circuit which are combined on a single chip and is effective in preventing deterioration in characteristics attributed to the propagation and interference of signals and noises between the circuit blocks.

1. A semiconductor device comprising:
a semiconductor substrate;
a first circuit region and a second circuit region which are independently provided on the semiconductor substrate;
a digital circuit block which comprises first elements and is formed on the first circuit region;
an analog circuit block which comprises second elements and is formed on the second circuit region;
a first power supply wiring and a first ground wiring which are located so as to surround the first circuit region and are connected to the first elements;
a second power supply wiring and a second ground wiring which are located so as to surround the second circuit region and are connected to the second elements;
a first capacitor which is located so as to surround the first circuit region and is connected between the first power supply wiring and the first ground wiring; and
a second capacitor which is located so as to surround the second circuit region and is connected between the second power supply wiring and the second ground wiring.

2. The semiconductor device according to claim 1, wherein the first and second capacitors are first and second MIS capacitors having a MIS structure respectively.

3. The semiconductor device according to claim 2, wherein
the first MIS capacitor comprises a first semiconductor region, a first dielectric film, and a first polysilicon electrode and is formed so as to overlap with the first power supply wiring and the first ground wiring,
the second MIS capacitor comprises a second semiconductor region, a second dielectric film, and a second polysilicon electrode and is formed so as to overlap with the second power supply wiring and the second ground wiring,
the first semiconductor region is connected to the first power supply wiring via a plurality of first power supply contacts,
the first polysilicon electrode is connected to the first ground wiring via a plurality of first ground contacts,
the second semiconductor region is connected to the second power supply wiring via a plurality of second power supply contacts, and
the second polysilicon electrode is connected to the second ground wiring via a plurality of second ground contacts,
the first semiconductor region being formed in a first element region under the first power supply wiring and the first ground wiring and having a different conductivity type from that of a second element region under the first circuit region,
the first dielectric film and the first polysilicon electrode being stacked on the first semiconductor region in that order,
the second semiconductor region being formed in a third element region under the second power supply wiring and the second ground wiring and having a different conductivity type from that of a fourth element region under the second circuit region,
the second dielectric film and the second polysilicon electrode being stacked on the second semiconductor region in that order.

4. The semiconductor device according to claim 3, wherein the first power supply wiring and the first ground wiring have a gap at a place on the periphery of the first circuit region, and the second power supply wiring and the second ground wiring have a gap at a place on the periphery of the second circuit region.

5. The semiconductor device according to claim 3, wherein the first power supply wiring and the first ground wiring surround the periphery of the first circuit region continuously, and the second power supply wiring and the second ground wiring surround the periphery of the second circuit region continuously.

6. The semiconductor device according to claim 1, wherein the first and second capacitors are first and second MIM capacitors having a MIM structure respectively.

7. The semiconductor device according to claim 6, wherein
the first MIM capacitor comprises the first power supply wiring, the fist ground wiring, and a first dielectric film,
the second MIM capacitor comprises the second power supply wiring, the second ground wiring, and a second dielectric film,
the first ground wiring is connected to the semiconductor substrate via a first substrate contact, and
the second ground wiring is connected to the semiconductor substrate via a second substrate contact,
the first power supply wiring comprising a different wiring layer from that of the first ground wiring and being formed so as to overlap with the first ground wiring,
the first dielectric film being formed between the layers of the first power supply wiring and the first ground wiring,
the second power supply wiring comprising a different wiring layer from that of the second ground wiring and being formed so as to overlap with the second ground wiring,
the second dielectric film being formed between the layers of the second power supply wiring and the second ground wiring.

8. The semiconductor device according to claim 7, wherein the first power supply wiring and the first ground wiring have a gap at a place on the periphery of the first circuit region, and the second power supply wiring and the second ground wiring have a gap at a place on the periphery of the second circuit region.

9. The semiconductor device according to claim 7, wherein the first power supply wiring, the first ground wiring, and the first dielectric film surround the periphery of the first circuit region continuously, and the second power supply wiring, the second ground wiring, and the second dielectric film surround the periphery of the second circuit region continuously.

10. The semiconductor device according to claim 1, wherein first and second pads used for external connections and connected to the first and second elements are located in the first and second circuit regions respectively.

11. The semiconductor device according to claim 1, wherein
a plurality of first wirings are placed parallel to one another above the first circuit region, and
a plurality of second wirings are placed parallel to one another above the second circuit region,
every other one of the first wirings being connected to the first power supply wiring,
the remaining first wirings being connected to the first ground wiring,
every other one of the second wirings being connected to the second power supply wiring,
the remaining second wirings being connected to the second ground wiring.
